(19) United States
(12) Patent Application Publication
(10) Pub. No.: US 2015/0280101 A1
(43) Pub. Date: Oct. 1, 2015

(54) ELECTRONIC COMPONENT, ELECTRONIC APPARATUS, AND MOVING OBJECT

(71) Applicant: SEIKO EPSON CORPORATION, Tokyo (JP)

(72) Inventor: Manabu KONDO, Matsumoto-shi (JP)

(21) Appl. No.: 14/644,849

(22) Filed: Mar. 11, 2015

(30) Foreign Application Priority Data
Mar. 25, 2014 (JP) 2014-062021

(51) Int. Cl. H01L 41/053; H03B 5/32; H03H 9/19

(52) U.S. Cl. CPC H01L 41/0533; H03H 9/19; H03B 5/32

(57) ABSTRACT

An electronic component includes a functional element, a mounting plate which has a first surface, on which the functional element is arranged, a second surface opposite to the first surface, and an outer peripheral surface connecting the first surface and the second surface, and a circuit board which is connected to the second surface through connection members. The circuit board and the mounting plate are different in thermal expansion coefficient, and the mounting plate is provided with slits from the outer peripheral surface toward the inside.

### BACKGROUND

1. Technical Field

The present invention relates to an electronic component, an electronic apparatus, and a moving object.

2. Related Art

As an electronic component which is used in a reference frequency signal source of a communication instrument, a measurement instrument, or the like, a quartz crystal oscillator is known. The quartz crystal oscillator requires a stable output frequency with respect to change in temperature with high accuracy. In general, of the quartz crystal oscillators, as a quartz crystal oscillator which obtains extremely high frequency stability, an oven controlled quartz crystal oscillator (OCXO) is known. The OCXO has a quartz crystal resonator which is housed in a thermostat oven controlled at constant temperature.

In this quartz crystal oscillator, in recent years, although there is demand for reduction in size, it is necessary to house an IC or the like in a package, in addition to the resonator element. For this reason, for example, JP-T-2001-500715 discloses a quartz crystal oscillator in which a resonator element is arranged on a pedestal arranged so as to cover a concave portion of a package where an IC is housed, thereby achieving reduction in size and securing a space for housing the IC or the like.

However, in the quartz crystal oscillator described in JP-T-2001-500715, the thermal expansion coefficient of the package (circuit board) made of ceramics is different from the thermal expansion coefficient of the pedestal (mounting plate) made of quartz crystal. For this reason, stress is generated in the connection member between the package and the pedestal due to heat (for example, reflow or the like) in a manufacturing process or change in temperature of an external environment, and the pedestal may be separated from the package.

### SUMMARY

An advantage of some aspects of the invention is to provide an electronic component capable of reducing a possibility of a mounting plate being separated from a circuit board. Another advantage of some aspects of the invention is that it provides an electronic apparatus and a moving object including the electronic component.

The invention can be implemented as the following forms or application examples.

### Application Example 1

An electronic component according to this application example includes a functional element, a mounting plate which has a first surface, on which the functional element is arranged, a second surface opposite to the first surface, and an outer peripheral surface connecting the first surface and the second surface, and a circuit board which is connected to the second surface through a connection member. The circuit board and the mounting plate are different in thermal expansion coefficient, and the mounting plate is provided with a slit.

In the electronic component according to this application example, for example, when the circuit board and the mounting plate are heated or cooled by heat (for example, reflow or the like) in a manufacturing process or change in temperature of an external environment, it is possible to absorb a difference in dimensional change due to the difference in thermal expansion coefficient between the circuit board and the mounting plate with the slit. As a result, it is possible to reduce stress which is generated in the connection member connecting the circuit board and the mounting plate, and to reduce the possibility of the mounting plate being separated from the circuit board.

### Application Example 2

In the electronic component according to the application example described above, the mounting plate may be a metal plate.

In general, since a metal, in particular, a metal having large thermal conductivity has a large thermal expansion coefficient, the difference between the thermal expansion coefficient of the metal plate and the thermal expansion coefficient of the circuit board increases. For this reason, for example, when the circuit board and the metallic mounting plate are heated or cooled by heat (for example, reflow or the like) in the manufacturing process or change in temperature of the external environment, the difference in dimensional change due to the difference in thermal expansion coefficient between the circuit board and the mounting plate increases. In the electronic component according to this application example, it is possible to absorb dimensional change between the circuit board and the metallic mounting plate due to change in temperature with the slit. As a result, it is possible to reduce stress which is generated in the connection member connecting the circuit board and the mounting plate, and to reduce the possibility of the mounting plate being separated from the circuit board.

### Application Example 3

In the electronic component according to the application example described above, the material of the metal plate may be one of copper, gold, silver, aluminum, and tungsten, or an alloy containing one of copper, gold, silver, aluminum, and tungsten as a main component.

In the electronic component according to this application example, even if a metal plate having large thermal conductivity and a large thermal expansion coefficient is used for the mounting plate, it is possible to reduce the possibility of the mounting plate being separated from the circuit board.

### Application Example 4

In the electronic component according to the application example described above, the mounting plate may be a quartz crystal plate.

In the electronic component according to this application example, it is possible to reduce the possibility of the mounting plate being separated from the circuit board.

### Application Example 5

In the electronic component according to the application example described above, two connection members may be provided, and the slit may be provided between the two connection members in plan view.

In the electronic component according to this application example, it is possible to absorb the difference in dimensional change due to the difference in thermal expansion coefficient between the circuit board and the mounting plate with the slit. Therefore, it is possible to more reliably reduce the possibility of the mounting plate being separated from the circuit board.

### Application Example 6

In the electronic component according to the application example described above, a plurality of slits may be provided.

In the electronic component according to this application example, it is possible to absorb the difference in dimensional change due to the difference in the thermal expansion coefficient between the circuit board and the mounting plate with a plurality of slits. Therefore, it is possible to more reliably reduce the possibility of the mounting plate being separated from the circuit board.

### Application Example 7

In the electronic component according to the application example described above, the mounting plate may be provided with a through hole which passes through the mounting plate.

In the electronic component according to this application example, it is possible to absorb the difference in dimensional change due to the difference in thermal expansion coefficient between the circuit board and the mounting plate with the through hole. Therefore, it is possible to more reliably reduce the possibility of the mounting plate being separated from the circuit board.

### Application Example 8

In the electronic component according to the application example described above, the functional element may include a resonator element.

In the electronic component according to this application example, it is possible to reduce the possibility of the mounting plate being separated from the circuit board.

### Application Example 9

In the electronic component according to the application example described above, the functional element may further include a heating element which heats the resonator element.

In the electronic component according to this application example, when the circuit board and the mounting plate are heated or cooled by change in temperature due to heat generated by the heating element, it is possible to absorb the difference in dimensional change due to the difference in thermal expansion coefficient between the circuit board and the mounting plate with the slit. Therefore, it is possible to reduce the possibility of the mounting plate being separated from the circuit board.

### Application Example 10

The electronic component according to the application example described above may further include an electronic element, the electronic element may be arranged on the circuit board, and the mounting plate may overlap the electronic element in plan view.

In the electronic component according to this application example, it is possible to reduce the possibility of the mounting plate being separated from the circuit board.

### Application Example 11

In the electronic component according to the application example described above, the electronic element may include an oscillation circuit for oscillating a resonator element.

In the electronic component according to this application example, it is possible to configure an oscillator with a reduce possibility of the mounting plate being separated from the circuit board.

### Application Example 12

An electronic apparatus according to this application example includes any of the electronic components described above.

Since the electronic apparatus according to this application example includes the electronic component which can reduce the possibility of the mounting plate being separated from the circuit board, for example, it is possible to improve reliability.

### Application Example 13

A moving object according to this application example includes any of the electronic components described above.

Since the moving object according to this application example includes the electronic component which can reduce the possibility of the mounting plate being separated from the circuit board, for example, it is possible to improve reliability.

### BRIEF DESCRIPTION OF THE DRAWINGS

The invention will be described with reference to the accompanying drawings, wherein like numbers reference like elements.

FIG. 1 is a sectional view schematically showing an electronic component according to this embodiment.

FIG. 2 is a plan view schematically showing the electronic component according to this embodiment.

FIG. 3 is a sectional view schematically showing a modification example of a mounting plate of the electronic component according to this embodiment.

FIG. 4 is a sectional view schematically showing an electronic component according to a first modification example of this embodiment.

FIG. 5 is a plan view schematically showing the electronic component according to the first modification example of this embodiment.

FIG. 6 is a sectional view schematically showing an electronic component according to a second modification example of this embodiment.

FIG. 7 is a sectional view schematically showing an electronic component according to a third modification example of this embodiment.

FIG. 8 is a functional block diagram of an electronic apparatus of this embodiment.

FIG. 9 is a diagram showing an example of a moving object of this embodiment.

### DESCRIPTION OF EXEMPLARY EMBODIMENTS

Hereinafter, exemplary embodiments of the invention will be described in detail referring to the drawings. The embodiments described below are not intended to unduly limit the content of the invention described in the appended claims. Besides, all of configurations described below are not necessarily indispensable requirements of the invention.

### 1. Electronic Component

First, an electronic component according to this embodiment will be described referring to the drawings. Hereinafter, an example where the electronic component according to this embodiment is an oven controlled quartz crystal oscillator (OCXO) will be described.

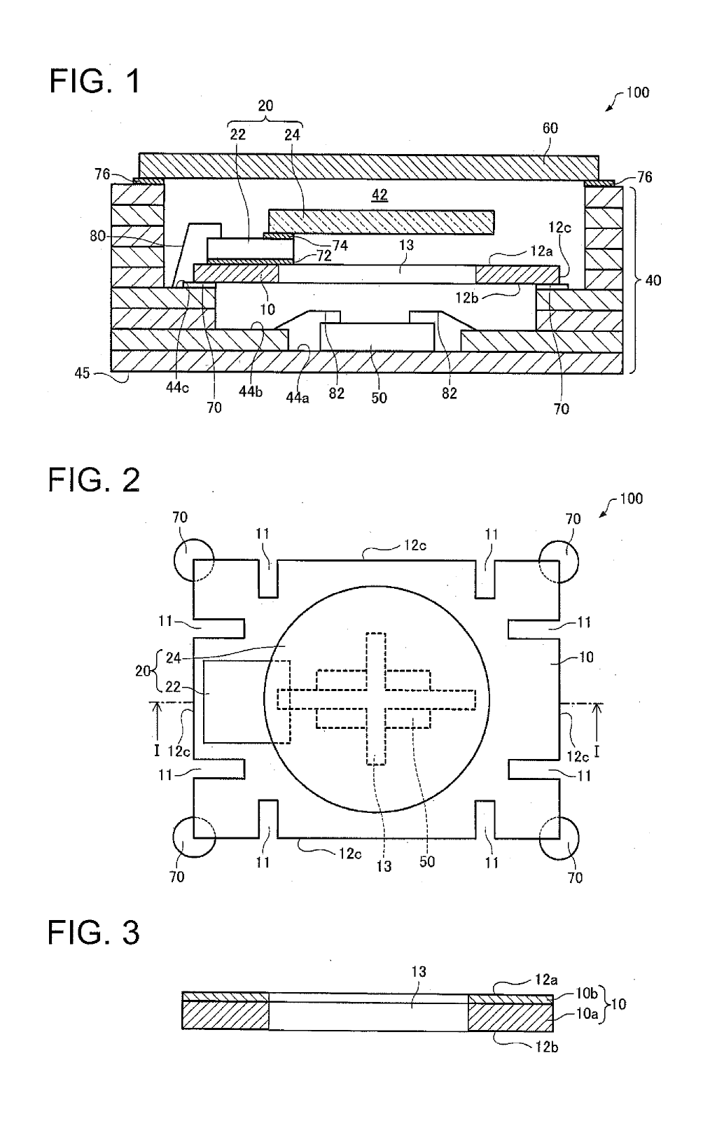

FIG. 1 is a sectional view schematically showing an electronic component 100 according to this embodiment. FIG. 2 is a plan view schematically showing the electronic component 100. FIG. 1 is a sectional view taken along the line I-I of FIG. 2.

As shown in FIGS. 1 and 2, the electronic component 100 includes a mounting plate 10, a functional element 20, a circuit board 40, an electronic element (oscillation IC) 50, and a lid 60. In FIG. 2, for convenience, the circuit board 40 and the lid 60 are omitted.

The mounting plate 10 is arranged on the circuit board 40. The mounting plate 10 is connected to the circuit board 40 through a plurality (in the example shown in the drawing, four) of connection members 70. That is, in the example shown in the drawing, the mounting plate 10 is supported at four points.

The connection members 70 are, for example, a conductive adhesive, an insulating adhesive, a solder material (solder, Ag solder, or the like), or the like. When the mounting plate 10 and the circuit board 40 are directly bonded to each other by solid phase bonding or fusion welding, the connection members 70 are, for example, a reaction layer of the material of the mounting plate 10 and the material of the circuit board 40.

The mounting plate 10 is, for example, a plate-shaped member. The planar shape (the shape when viewed from a direction perpendicular to a first surface (upper surface) 12a of the mounting plate 10) of the mounting plate 10 is, for example, a quadrangle (rectangle). The mounting plate 10 has a first surface 12a, a second surface (lower surface) 12b opposite to the first surface 12a, and an outer peripheral surface 12c connecting the first surface 12a and the second surface 12b.

As shown in FIG. 2, the second surface 12b of the mounting plate 10 is connected to a third surface 44c of the circuit board 40 through a plurality of connection members 70. In the example shown in the drawing, the planar shape of the second surface 12b of the mounting plate 10 is a quadrangle, and four corner portions of the quadrangle are connected to the circuit board 40 through the connection members 70.

In the example shown in the drawing, the outer peripheral surface 12c of the mounting plate 10 is constituted by four surfaces (side surfaces). The mounting plate 10 is provided with slits 11 which pass through the first surface 12a and the second surface 12b of the mounting plate 10 and are opened to the end portions of the mounting plate 10. As shown in FIG. 2, the slits 11 are within a region partially surrounded by the outer peripheral surface 12c of the mounting plate 10. As shown in FIG. 2, the slits 11 are provided between the two connection members 70 in plan view (when viewed from the direction perpendicular to the first surface 12a of the mounting plate 10). Here, the slits 11 being provided between the two connection members 70 in plan view means that, when a virtual line (not shown) connecting one connection member 70 and the other connection member 70 is drawn on the mounting plate 10 at the shortest distance in plan view, the slits 11 are provided in a direction intersecting the virtual line. In the example shown in the drawing, the slits 11 are provided between two adjacent connection members 70 along the outer peripheral surface 12c of the mounting plate 10 in plan view. A plurality of slits 11 (in the example shown in the drawing, two) are provided between the two connection members 70. Though not shown, one slit 11 may be provided between the two connection members 70, or three or more slits 11 may be provided between the two connection members 70.

The mounting plate 10 is provided with a through hole 13 which passes through the mounting plate 10. The through hole 13 passes through the first surface 12a and the second surface 12b. The through hole 13 is provided in, for example, the central portion of the mounting plate 10 in plan view. In the example shown in the drawing, while the planar shape of the through hole 13 is a shape (cross shape) in which two lines are orthogonal to each other and the two lines are divided at the center, a circular shape, an elliptical shape, a shape surrounded by a curve, a polygonal shape, or the like may be used, and the shape is not particularly limited.

The mounting plate 10 is a metal plate having high thermal conductivity. The material of the mounting plate 10 is one of copper, gold, silver, aluminum, and tungsten. The material of the mounting plate 10 may be an alloy containing one of copper, gold, silver, aluminum, and tungsten as a main component. When the material of the mounting plate 10 is an alloy containing the above-described metal as a main component, a sub component is, for example, a metal other than the main component. The material of the mounting plate 10 is not limited to a metal, and ceramic, glass, glass epoxy, resin, semiconductor crystal, such as silicon, piezoelectric single crystal, such as lithium tantalate, lithium niobate, or quartz crystal, or the like may be used. The mounting plate 10 may be a plate where at least the first surface 12a is made of a metal, for example, one of copper, gold, silver, aluminum, and tungsten, or an alloy containing one of copper, gold, silver, aluminum, and tungsten as a main component.

FIG. 3 is a sectional view schematically showing a modification example of the mounting plate 10. As shown in FIG. 3, in the mounting plate 10, if at least the first surface 12a is made of a metal, other portions may be made of metal, resin, ceramics, glass, glass epoxy, semiconductor crystal, such as silicon, piezoelectric single crystal, such as lithium tantalate, lithium niobate, or quartz crystal, or the like. In the example shown in FIG. 3, the mounting plate 10 has a first layer 10a, and a second layer 10b provided on the first layer 10a. The first layer 10a is a layer made of a material illustrated as other portions described above, and the second layer 10b is a layer made of a metal. The first surface 12a of the mounting plate 10 is the surface (upper surface) of the second layer 10b.

As shown in FIG. 1, the mounting plate 10 is arranged to face the resonator element 24. In the example shown in the drawing, an interval is provided between the mounting plate 10 and the resonator element 24, and the heating element 22, a connection member 72, and a connection member 74 are interposed between the mounting plate 10 and the resonator element 24. The mounting plate 10 is arranged to face the electronic element 50. In the example shown in the drawing, an interval is provided between the mounting plate 10 and the electronic element 50.

As shown in FIG. 2, the mounting plate 10 overlaps the resonator element 24 in plan view. In the example shown in the drawing, the mounting plate 10 is positioned below the resonator element 24. The mounting plate 10 overlaps the electronic element 50 in plan view. In the example of the drawing, the mounting plate 10 is positioned above the electronic element 50 in plan view.

In addition to the heating element 22, the connection member 72, and the connection member 74, other components may be arranged between the mounting plate 10 and the resonator element 24. For example, an electronic component, a plate-shaped member, and the like may be arranged on the mounting plate 10 or the resonator element 24. Other components may be arranged between the mounting plate 10 and the electronic element 50. For example, an electronic component, a plate-shaped member, and the like may be arranged on the mounting plate 10 or the electronic element 50.

In the electronic component 100, the mounting plate 10 is provided, whereby it is possible to secure a space where the functional element 20, or an element, such as the electronic element 50, is arranged, while achieving reduction in size.

The functional element 20 is arranged on the first surface 12a of the mounting plate 10. The functional element 20 includes a heating element 22 and a resonator element 24.

The heating element 22 is arranged on the mounting plate 10. The heating element 22 is connected onto the mounting plate 10 (the first surface 12a of the mounting plate 10) through the connection member 72. Similarly to the connection members 70, the connection member 72 is an adhesive, a solder material, a reaction layer, or the like. The heating element 22 has a plurality of electrodes (pads) on the upper surface of the heating element 22. Each electrode (pad) provided on the upper surface of the heating element 22 is electrically connected to each electrode provided on the third surface 44c of the circuit board 40 by a wire 80.

The heating element 22 is, for example, a heating IC. The heating IC includes, for example, a heating circuit and a temperature sensor. The heating circuit is a circuit which generates heat when a current flows in a resistor. The heating circuit may be an element which generates heat when power of a power transistor or the like is input. In the electronic component 100, for example, the resonator element 24 is arranged on the heating circuit. The temperature sensor is arranged close to the resonator element 24 and outputs a signal according to temperature (for example, a signal having a voltage according to temperature).

Here, the path of heat generated by the heating element 22 will be described. Heat generated by the heating element 22 is transmitted to the resonator element 24 through the connection member 74 by heat conduction. With this, the resonator element 24 is heated. Furthermore, heat generated by the heating element 22 is transmitted to the mounting plate 10 through the connection member 72 by heat conduction. With this, the mounting plate 10 is heated. Heat is emitted (radiated) from the heated mounting plate 10. The resonator element 24 and the electronic element 50 are heated by heat emission (heat radiation) from the mounting plate 10. Furthermore, heat generated by the heating element 22 is transmitted to the electronic element 50 or an element (not shown) arranged on a lower surface 45 of the circuit board 40 through the connection member 72, the mounting plate 10, the connection members 70, and the circuit board 40 by heat conduction. With this, the electronic element 50 or the element arranged on the lower surface 45 of the circuit board 40 is heated.

The resonator element 24 is arranged on the heating element 22. The resonator element 24 is connected onto the heating element 22 through the connection member 74. In the example shown in the drawing, electrodes provided on a part of the lower surface of the resonator element 24 are connected to the electrodes (pads) provided on the upper surface of the heating element 22 by the conductive connection member 74. Similarly to the connection members 70, the connection member 74 is, for example, an adhesive, a solder material, a reaction layer, or the like. Though not shown, the electrodes (pads) provided on the upper surface of the resonator element 24 may be electrically connected to the electrodes provided on the circuit board 40 by wires. If the resonator element 24 and the heating element 22 are mechanically connected together by the connection member 74, since heat generated by the heating element 22 is transmitted to the resonator element 24 through the connection member 74, the resonator element 24 and the heating element 22 may not be electrically connected together.

As shown in FIG. 2, the resonator element 24 is arranged within the outer peripheral portion (outer edge) of the mounting plate 10 in plan view. Here, the resonator element 24 being arranged within the outer peripheral portion (outer edge) of the mounting plate 10 in plan view includes a case where the entire outer edge of the resonator element 24 is inside of the outer edge of the mounting plate 10 in plan view (see FIG. 2), a case where a part of the outer edge of the resonator element 24 overlaps a part of the outer edge of the mounting plate 10 in plan view and another part of the outer edge of the resonator element 24 is inside of the outer edge of the mounting plate 10 in plan view, and a case where the entire outer edge of the resonator element 24 overlaps the outer edge of the mounting plate 10 in plan view and a region inside the outer edge of the resonator element 24 is inside of the outer edge of the mounting plate 10. In the example of FIG. 2, the resonator element 24 overlaps a part of the mounting plate 10 in plan view as a whole.

The resonator element 24 is an element whose output frequency has temperature characteristics. Specifically, the resonator element 24 is a resonator element (quartz crystal resonator) which uses quartz crystal as a substrate material, and for example, an SC cut or AT cut quartz crystal resonator is used. As this quartz crystal resonator, for example, a mesa quartz crystal resonator where a central portion is thicker than a peripheral portion and the central portion (thick portion) becomes a resonating portion may be used. However, the resonator element 24 may be a surface acoustic wave (SAW) resonator or a micro electro mechanical systems (MEMS) resonator. As the substrate material of the resonator element 24, in addition to quartz crystal, piezoelectric single crystal, such as lithium tantalate or lithium niobate, a piezoelectric material, such as piezoelectric ceramics of lead zirconate titanate or the like, a silicon semiconductor material, or the like may be used. A unit configured to excite the resonator element 24 may use a piezoelectric effect, or electrostatic driving using Coulomb force. The resonator element 24 may be an element which detects a physical quantity, for example, an element for an inertial sensor (acceleration sensor, gyro sensor, or the like) or a force sensor (tilt sensor or the like).

The circuit board 40 is, for example, a ceramic package. In the example shown in the drawing, the circuit board 40 is a ceramic laminate package which is formed by molding and laminating a ceramic green sheet and then performing baking. The circuit board 40 has a concave portion, and the mounting plate 10, the heating element 22, the resonator element 24, and the electronic element 50 are housed in a space (housing chamber) 42 inside the concave portion. In the example shown in the drawing, an opening is provided in the upper portion of the circuit board 40, and the housing chamber 42 is formed by covering the opening with the lid 60.

The thermal expansion coefficient (linear expansion coefficient) of the circuit board 40 is different from the thermal expansion coefficient (linear expansion coefficient) of the mounting plate 10. In the electronic component 100, the material of the circuit board 40 is, for example, ceramics, and the material of the mounting plate 10 is, for example, a metal (Cu). For example, the thermal expansion coefficient of ceramics is about 3 to 8×10⁻⁶/° C., and the thermal expansion coefficient of a metal, such as Cu, is about 17×10⁻⁶/° C. In general, the thermal expansion coefficient of a metal, particularly, a metal having large thermal conductivity is greater than the thermal expansion coefficient of ceramics. For this reason, the circuit board 40 has a small thermal expansion coefficient and small dimensional change to change in temperature compared to the mounting plate 10.

The circuit board 40 has a first surface 44a, a second surface 44b, and a third surface 44c. In the example shown in the drawing, the first surface 44a is the upper surface of a first layer among nine layers constituting the circuit board 40, the second surface 44b is the upper surface of a second layer, and the third surface 44c is the upper surface of a fourth layer. Since the first surface 44a, the second surface 44b, and the third surface 44c are different in height, two steps are formed in the inside surface of the concave portion by the first surface 44a, the second surface 44b, and the third surface 44c. The first surface 44a is the inner bottom surface of the concave portion.

The electronic element 50 is arranged on the first surface 44a. The second surface 44b is provided with electrodes (not shown) wire-bonded to the electrodes of the electronic element 50. The second surface 12b of the mounting plate 10 is connected to the third surface 44c through a plurality of connection members 70. The third surface 44c is provided with electrodes (not shown) wire-bonded to the electrodes of the heating element 22.

Inside or on the surface of the circuit board 40, wirings (not shown) for electrically connecting the electrodes wire-bonded to the electrodes of the heating element 22 and the electrodes wire-bonded to the electrodes of the electronic element 50 are provided.

A power supply terminal (not shown), a ground terminal, or other external terminals (an output terminal of an oscillation signal or the like) are provided on the lower surface 45 (the surface opposite to the first surface 44a) of the circuit board 40, and wirings for electrically connecting the power supply terminal, the ground terminal, the heating element 22, and the electronic element 50 or wirings for electrically connecting other external terminals and the electronic element 50 are provided inside or on the surface of the circuit board 40. An element, such as a resistor or a coil constituting the OCXO, may be provided on the lower surface 45 of the circuit board 40.

The electronic element 50 is arranged on the circuit board 40. The electronic element 50 is connected onto the circuit board 40 (first surface 44a) by an adhesive (not shown) or the like. The electronic element 50 has a plurality of electrodes (pads) provided on the upper surface. Each electrode (pad) provided on the upper surface of the electronic element 50 is electrically connected to each electrode provided on the second surface 44b of the circuit board 40 by a wire 82.

As shown in FIG. 2, the electronic element 50 is arranged within the outer peripheral portion (outer edge) of the mounting plate 10 in plan view. Here, the electronic element 50 being arranged within the outer peripheral portion (outer edge) of the mounting plate 10 in plan view includes a case where the outer edge of the electronic element 50 is inside of the outer edge of the mounting plate 10 in plan view, a case where a part of the outer edge of the electronic element 50 overlaps a part of the outer edge of the mounting plate 10 in plan view and another part of the outer edge of the electronic element 50 is inside of the outer edge of the mounting plate 10 in plan view, and a case where the entire outer edge of the electronic element 50 overlaps the outer edge of the mounting plate 10 in plan view and a region inside the outer edge of the electronic element 50 is inside of the outer edge of the mounting plate 10.

The electronic element 50 is, for example, an oscillation IC. The oscillation IC includes, for example, an oscillation circuit and a temperature control circuit.

The oscillation circuit is a circuit which is connected to both ends of the resonator element 24, and amplifies a signal output from the resonator element 24 and feeds back the signal to the resonator element 24, thereby oscillating the resonator element 24. A circuit constituted by the resonator element 24 and the oscillation circuit may be, for example, various oscillation circuits, such as a pierce oscillation circuit, an inverter oscillation circuit, a Colpitts oscillation circuit, and a Hartley oscillation circuit.

The temperature control circuit is a circuit which controls the amount of a current flowing in the resistor of the heating circuit based on an output signal (temperature information) of the temperature sensor and maintains the resonator element 24 at constant temperature. For example, the temperature control circuit performs control such that a desired current flows in the resistor of the heating circuit when the current temperature determined from the output signal of the temperature sensor is lower than a set reference temperature, and a current does not flow in the resistor of the heating circuit when the current temperature is higher than the reference temperature. For example, the temperature control circuit may perform control such that the amount of a current flowing in the resistor of the heating circuit increases or decreases according to the difference between the current temperature and the reference temperature.

The lid 60 covers the opening of the circuit board 40. The shape of the lid 60 is, for example, a plate shape. As the lid 60, for example, a metal plate made of the same material as the circuit board 40, kovar, 42 alloy, stainless steel, or the like may be used. The lid 60 is bonded to the circuit board through a connection member 76, such as a seam ring, low melting point glass, or adhesive.

The electronic component 100 has, for example, the following features.

The electronic component 100 includes the functional element 20, the mounting plate 10 which has the first surface 12a, on which the functional element 20 is arranged, the second surface 12b, and the outer peripheral surface 12c connecting the first surface 12a and the second surface 12b, and the circuit board 40 which is connected to the second surface 12b of the mounting plate 10 through the connection members 70. The circuit board 40 and the mounting plate 10 are different in thermal expansion coefficient, and the mounting plate 10 is provided with the slit 11 from the outer peripheral surface 12c toward the inside. For this reason, when the circuit board 40 and the mounting plate 10 are heated or cooled by heat (for example, reflow or the like) in the manufacturing process or change in temperature of the external environment, it is possible to absorb the difference in dimensional change due to the difference in thermal expansion coefficient between the circuit board 40 and the mounting plate 10 with the slit 11. As a result, in the electronic component 100, it is possible to reduce stress which is generated in the connection members 70 connecting the circuit board 40 and the mounting plate 10, and to reduce the possibility of the mounting plate 10 being separated from the circuit board 40.

In the electronic component 100, the slit 11 is provided between the two connection members 70 in plan view. For this reason, it is possible to more absorb the difference in dimensional change due to the difference in thermal expansion coefficient between the circuit board 40 and the mounting plate 10. Therefore, it is possible to more reliably reduce the possibility of the mounting plate 10 being separated from the circuit board 40.

In the electronic component 100, a plurality of slits 11 are provided. For this reason, it is possible to absorb the difference in dimensional change due to the difference in thermal expansion coefficient between the circuit board 40 and the mounting plate 10 with a plurality of slits 11. Therefore, it is possible to more reliably reduce the possibility of the mounting plate 10 being separated from the circuit board 40.

In the electronic component 100, the mounting plate 10 is provided with the through hole 13 which passes through the mounting plate 10. For this reason, it is possible to absorb the difference in dimensional change due to the difference in thermal expansion coefficient between the circuit board 40 and the mounting plate 10 with the through hole 13. Therefore, it is possible to more reliably reduce the possibility of the mounting plate 10 being separated from the circuit board 40.

The electronic component 100 includes the mounting plate (metal plate) 10, the heating element 22 arranged on the mounting plate 10, and the resonator element 24 arranged on the heating element 22. In this configuration, when the circuit board 40 and the mounting plate 10 are heated or cooled by change in temperature due to heat generated by the heating element 22, it is possible to absorb the difference in dimensional change due to the difference in thermal expansion coefficient between the circuit board 40 and the mounting plate 10 with the slits. Therefore, it is possible to reduce the possibility of the mounting plate 10 being separated from the circuit board 40. Furthermore, since the resonator element 24 is arranged on the heating element 22, heat generated by the heating element 22 is transmitted to the resonator element 24 by heat conduction without passing through other members (excluding the connection member 74). Therefore, for example, it is possible to shorten the conduction path of heat and to efficiently heat the resonator element 24 compared to a case where the resonator element 24 is arranged on another member, such as the mounting plate 10 or the circuit board 40.

In the electronic component 100, the mounting plate 10 overlaps the resonator element 24 in plan view. For this reason, it is possible to heat the resonator element 24 by heat emission (heat radiation) from the mounting plate 10 heated by the heating element 22. Even when other components are arranged between the mounting plate 10 and the resonator element 24, for example, an electronic component, a plate-shaped member, and the like are arranged on the mounting plate 10 or the resonator element 24, other components are heated by heat emitted (radiated) from the mounting plate 10, and as a result, the resonator element 24 is heated by heat emitted (radiated) from other components.

That is, in the electronic component 100, it is possible to heat the resonator element 24 by both of heat conduction and heat emission (heat radiation). Therefore, it is possible to efficiently heat the resonator element 24. For this reason, when the electronic component 100 is an OCXO, since it becomes easy to uniformly heat the resonator element 24, for example, it is possible to increase a frequency stabilization temperature and to improve frequency stability.

In the electronic component 100, the resonator element 24 is arranged within the outer peripheral portion of the mounting plate 10 in plan view. For this, reason, it is possible to more uniformly heat the resonator element 24 by heat emission (heat radiation) from the mounting plate 10.

The electronic component 100 includes the circuit board 40, and the electronic element 50 arranged on the circuit board 40, and the mounting plate 10 overlaps the electronic element 50 in plan view. For this reason, it is possible to heat the electronic element 50 by heat emission (heat radiation) from the mounting plate 10. With this, it is possible to suppress change in characteristics due to change in temperature of the electronic element 50. Even when other components are arranged between the mounting plate 10 and the electronic element 50, for example, an electronic component, a plate-shaped member, and the like are arranged on the mounting plate 10 or the electronic element 50, other components are heated by heat emitted (radiated) from the mounting plate 10, and as a result, the electronic element 50 is heated by heat emitted (radiated) from other components.

In the electronic component 100, the electronic element 50 includes the oscillation circuit for oscillating the resonator element 24. In the electronic component 100, since it is possible to heat the electronic element 50 in the above-described manner, it is possible to reduce errors due to the temperature characteristics of the oscillation circuit, for example, frequency fluctuation or the like.

In the electronic component 100, the material of the mounting plate 10 is one of copper, gold, silver, aluminum, and tungsten, or an alloy containing one of copper, gold, silver, aluminum, and tungsten as a main component. For this reason, the mounting plate 10 can have high thermal conductivity. In general, since the thermal expansion coefficient of a metal, particularly, a metal having large thermal conductivity is large, the difference between the thermal expansion coefficient of the metal plate and the thermal expansion coefficient of the circuit board increases. For this reason, for example, when the circuit board 40 and the metallic mounting plate 10 are heated or cooled by heat (for example, reflow or the like) in the manufacturing process or change in temperature of the external environment, the difference in dimensional change due to the difference in thermal expansion coefficient between the circuit board 40 and the mounting plate 10 increases. In this configuration, it is possible to absorb dimensional change between the circuit board 40 and the metallic mounting plate 10 due to change in temperature with the slits 11. As a result, it is possible to reduce stress which is generated in the connection members connecting the circuit board 40 and the mounting plate 10, and to reduce the possibility of the mounting plate being separated from the circuit board. Furthermore, in the electronic component 100, it is possible to efficiently heat the resonator element 24 and the electronic element 50.

### 2. Method of Manufacturing Electronic Component

Next, a method of manufacturing the electronic component 100 according to this embodiment will be described referring to FIGS. 1 and 2.

First, the circuit board 40 is prepared. The circuit board 40 is formed, for example, by molding and laminating a ceramic green sheet and then performing baking. Next, the mounting plate 10 is prepared. In the mounting plate 10, the slits 11 and the through hole 13 are formed. The slits 11 and the through hole 13 are formed, for example, by etching, punching, cutting, or the like the metal plate. A method of forming the slits 11 and the through hole 13 is not particularly limited.

Next, the electronic element 50, the mounting plate 10, and the functional element 20 are housed in the housing chamber 42 of the circuit board 40.

Specifically, for example, the electronic element 50 is connected to the first surface 44a of the circuit board 40 by an adhesive, and each electrode (pad) provided on the upper surface of the electronic element 50 is electrically connected to each electrode provided on the second surface 44b of the circuit board 40 by the wire 82. Next, the mounting plate 10 is connected to the third surface 44c of the circuit board 40 by the connection members 70. Next, the heating element 22 is connected onto the mounting plate 10 by the connection member 72, and the resonator element 24 is connected onto the heating element 22 by the connection member 74. Next, each electrode (pad) provided on the upper surface of the heating element 22 is electrically connected to each electrode provided on the third surface 44c of the circuit board 40 by the wire 80.

Next, the frequency adjustment of the resonator element 24 is performed. The frequency adjustment of the resonator element 24 is performed, for example, by etching the electrodes (not shown) on the resonator element 24 or the surface of the resonator element 24 with laser or ion beams while oscillating the resonator element 24. The frequency adjustment of the resonator element 24 may be performed by adding mass to the electrodes (not shown) on the resonator element 24 or the surface of the resonator element 24 using a method, such as vapor deposition, sputtering, spraying, or coating.

Next, the lid 60 is bonded to the circuit board 40 through the connection member 76. This process is performed in a reduced pressure atmosphere or in an inert gas atmosphere, such as nitrogen, argon, or helium, whereby the space for housing the resonator element 24 and the like can be in a reduced pressure state or in a state where inert gas is sealed. The frequency adjustment of the resonator element 24 may be performed after this process. In this case, the lid 60 is made of a transparent material to laser or ion beams.

With the above process, it is possible to manufacture the electronic component 100.

### 3. Modification Examples of Electronic Component

Next, modification examples of the electronic component according to this embodiment will be described. In electronic components (electronic components 200, 300, and 400) according to the modification examples of this embodiment described below, the members having the same functions as the members of the above-described electronic component 100 are represented by the same reference numerals, and detailed description thereof will not be repeated.

### 1. First Modification Example

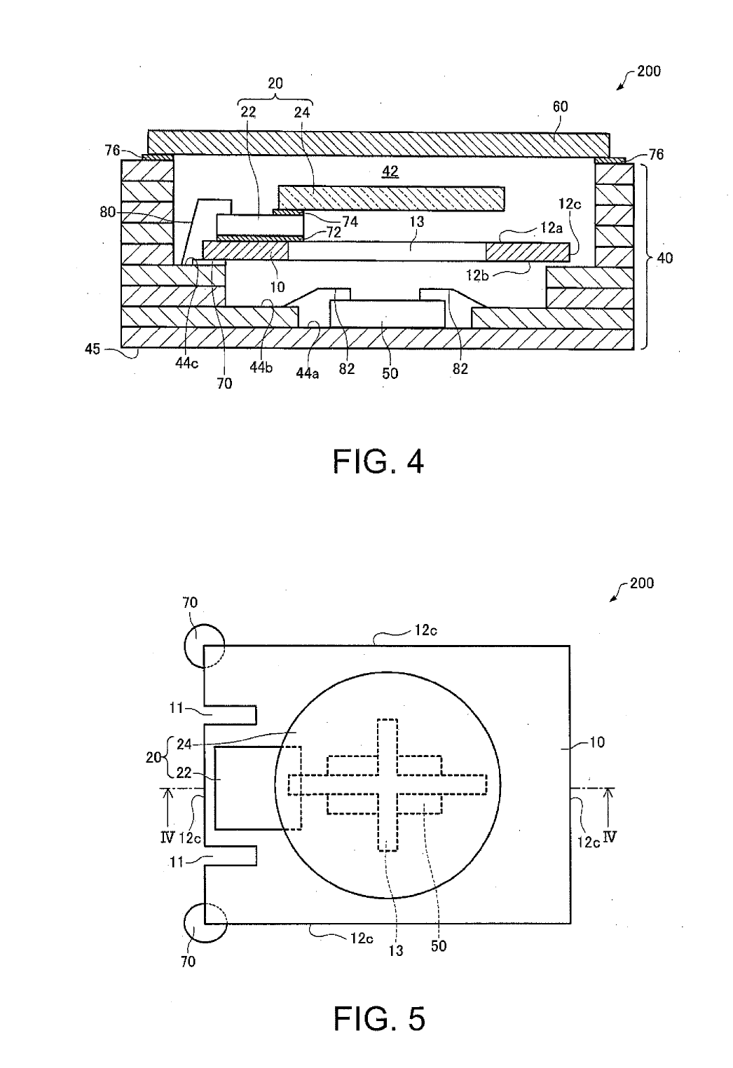

First, a first modification example of the electronic component according to this embodiment will be described referring to the drawings. FIG. 4 is a sectional view schematically showing an electronic component 200 according to the first modification example of this embodiment. FIG. 5 is a plan view schematically showing the electronic component 200. FIG. 4 is a sectional view taken along the line IV-IV of FIG. 5. In FIG. 5, for convenience, the circuit board 40 and the lid 60 are omitted.

The electronic component 200 is different from the above-described electronic component 100 in that, as shown in FIGS. 4 and 5, the second surface 12b of the mounting plate 10 and the circuit board 40 are connected together through two connection members 70.

The mounting plate 10 is connected onto the circuit board 40 through the two connection members 70. That is, the mounting plate 10 is supported at two points. The two connection members 70 are provided in corner portions with the short side of the mounting plate 10 sandwiched therebetween in plan view. Though not shown, the two connection members 70 may be provided in corner portions with the long side of the mounting plate 10 sandwiched therebetween in plan view.

As shown in FIG. 5, two slits 11 are provided between the two connection members 70 in plan view. Though not shown, one slit 11 may be provided between the two connection members 70, or three or more slits 11 may be provided between the two connection members 70.

### 2. Second Modification Example

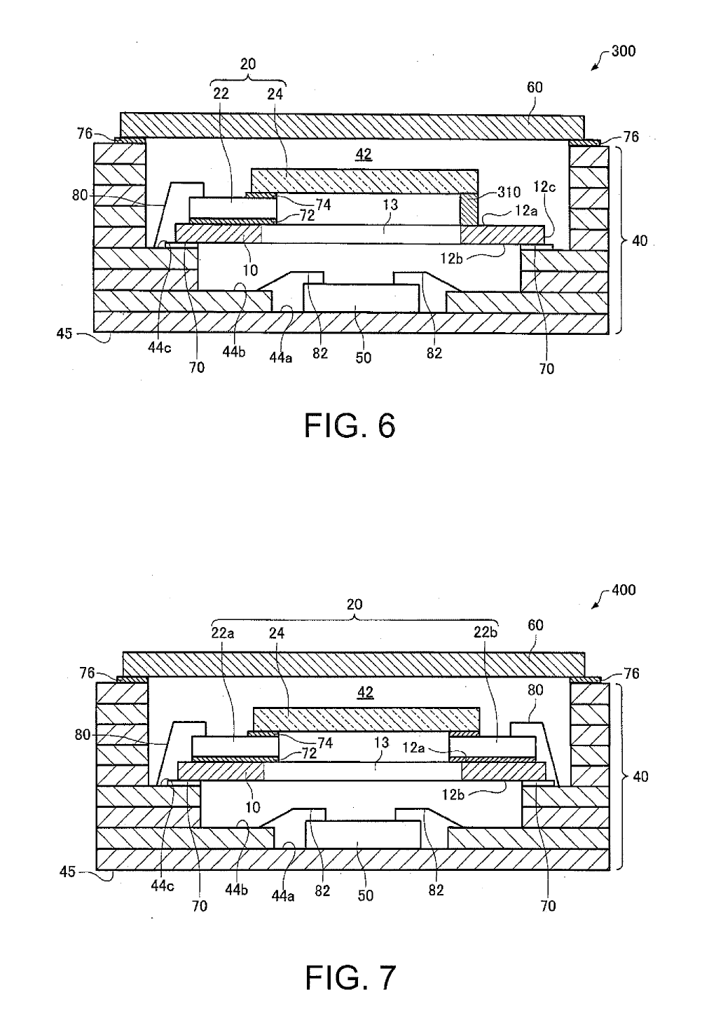

Next, a second modification example of the electronic component according to this embodiment will be described referring to the drawings. FIG. 6 is a sectional view schematically showing an electronic component 300 according to the second modification example of this embodiment. FIG. 6 corresponds to FIG. 1.

In the electronic component 300, as shown in FIG. 6, the mounting plate 10 is provided with a convex portion 310.

The convex portion 310 is provided on the first surface 12a of the mounting plate 10. The convex portion 310 protrudes toward the resonator element 24. That is, the distance (shortest distance) between the convex portion 310 and the resonator element 24 is smaller than the distance (shortest distance) between the mounting plate 10 (first surface 12a) and the resonator element 24. In the example shown in the drawing, the convex portion 310 is in contact with the resonator element 24. For example, when the resonator element 24 has a resonating region and a non-resonating region, the convex portion 310 is in contact with the non-resonating region of the resonator element 24. Though not shown, the convex portion 310 and the resonator element 24 may be separated from each other.

The convex portion 310 overlaps the resonator element 24 in plan view. A plurality of convex portions 310 may be provided at positions overlapping the resonator element 24 in plan view.

The convex portion 310 is, for example, a member separate from the mounting plate 10. It is preferable that the convex portion 310 has high thermal conductivity. The material of the convex portion 310 is, for example, one of copper, gold, silver, aluminum, and tungsten, or an alloy containing copper, gold, silver, aluminum, and tungsten as a main component.

The convex portion 310 may be a member integrated with the mounting plate 10. For example, a part of the first surface 12a of the mounting plate 10 may protrude to form the convex portion 310.

In the electronic component 300, the mounting plate 10 is provided with the convex portion 310 which protrudes toward the resonator element 24, and the convex portion 310 overlaps the resonator element 24 in plan view. For this reason, when the convex portion 310 is in contact with the resonator element 24, heat generated by the heating element 22 is transmitted to the resonator element 24 through the connection member 72, the mounting plate 10, and the convex portion 310 by heat conduction.

When the convex portion 310 is not in contact with the resonator element 24, heat generated by the heating element 22 is transmitted to the convex portion 310 through the connection member 72 and the mounting plate 10 by heat conduction, and the convex portion 310 is heated. Then, the resonator element 24 is heated by heat emission (heat radiation) from the heated convex portion 310 near the resonator element 24.

In this way, in the electronic component 300, the mounting plate 10 is provided with the convex portion 310, whereby it is possible to increase the path of heat for heating the resonator element 24 compared to the example of the electronic component 100 described above. Therefore, in the electronic component 300, it is possible to more uniformly heat the resonator element 24.

### 3. Third Modification Example

Next, a third modification example of the electronic component according to this embodiment will be described referring to the drawings. FIG. 7 is a sectional view schematically showing an electronic component 400 according to the third modification example of this embodiment. FIG. 7 corresponds to FIG. 1.

In the electronic component 400, as shown in FIG. 7, two heating elements 22a and 22b are arranged on the mounting plate 10.

The resonator element 24 is arranged on the two heating elements 22a and 22b. The number of heating elements 22a and 22b provided on the mounting plate 10 is not particularly limited, and three or more heating elements may be provided. The heating elements 22a and 22b are provided at positions overlapping the resonator element 24 in plan view. In the example shown in the drawing, the heating element 22b is provided instead of the above-described convex portion 310 (see FIG. 6).

In the electronic component 400, since a plurality of heating elements 22 are arranged on the mounting plate 10, and the resonator element 24 is arranged on a plurality of heating elements 22a and 22b, it is possible to more uniformly heat the resonator element 24. The resonator element 24 may be arranged on one heating element (for example, only the heating element 22a), and may not be arranged on (may not be connected to) the other heating element (for example, the heating element 22b). Even in this case, since the resonator element 24 is heated by conduction from the heating element 22a, radiation from the mounting plate 10 heated by the heating element 22a and the heating element 22b, and radiation from the heating element 22b, it is possible to more uniformly heat the resonator element 24.

### 4. Electronic Apparatus

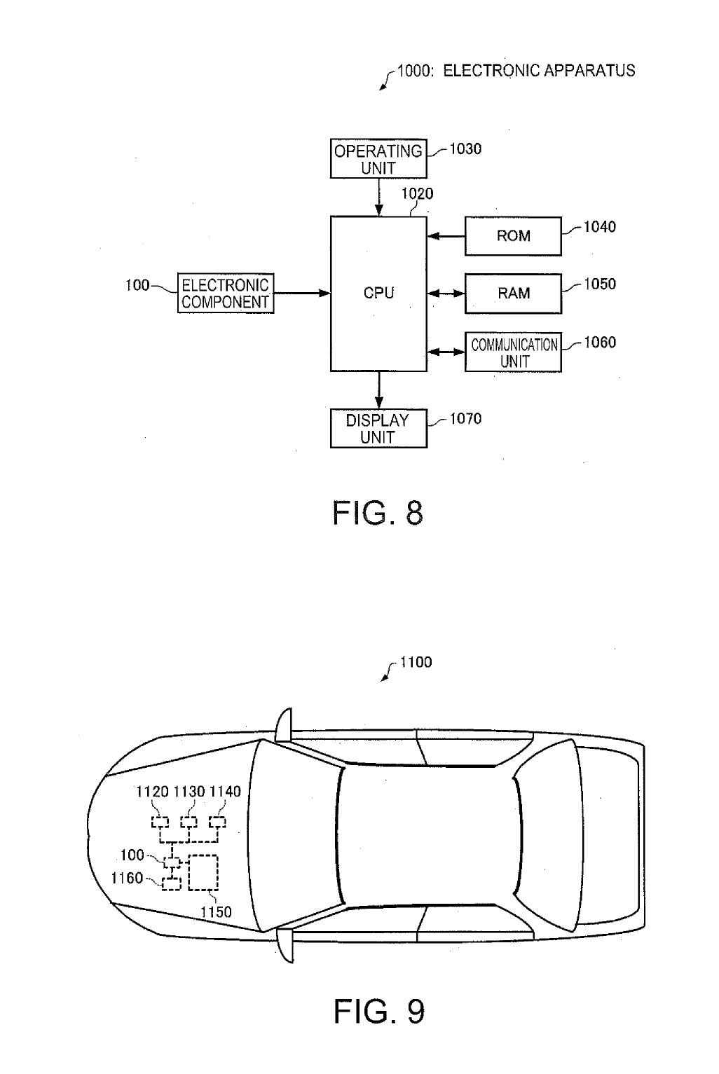

Next, an electronic apparatus according to this embodiment will be described referring to the drawings. FIG. 8 is a functional block diagram of the electronic apparatus of this embodiment.

An electronic apparatus 1000 includes an electronic component according to an embodiment of the invention. Here, as shown in FIG. 8, a case where the electronic component 100 is used as an electronic component according to an embodiment of the invention will be described.

The electronic apparatus 1000 further includes a central processing unit (CPU) 1020, an operating unit 1030, a read only memory (ROM) 1040, a random access memory (RAM) 1050, a communication unit 1060, and a display unit 1070. In the electronic apparatus of this embodiment, a part of the components (respective units) of FIG. 8 may be omitted or modified, or other components may be added.

Though not shown, the electronic component 100 includes a resonator element and a heating element, and generates an oscillation signal based on the oscillation of the resonator element heated by the heating element. The oscillation signal is output to the CPU 1020.

The CPU 1020 performs various kinds of computation processing or control processing based on the oscillation signal input from the electronic component 100 according to a program stored in the ROM 1040 or the like. In addition, the CPU 1020 performs various kinds of processing according to an operation signal from the operating unit 1030, processing for controlling the communication unit 1060 in order to perform data communication with an external device, processing for transmitting a display signal in order to display various kinds of information on the display unit 1070, and the like.

The operating unit 1030 is an input device which is constituted by operation keys, button switches, or the like, and outputs an operation signal according to a user's operation to the CPU 1020.

The ROM 1040 stores a program, data, and the like for various kinds of computation processing or control processing in the CPU 1020.

The RAM 1050 is used as a work area of the CPU 1020, and temporarily stores the program or data read from the ROM 1040, data input from the operating unit 1030, arithmetic results of the CPU 1020 according to various programs, and the like.

The communication unit 1060 performs various kinds of control in order to establish data communication between the CPU 1020 and the external device.

The display unit 1070 is a display device which is constituted by a liquid crystal display (LCD) or the like, and displays various kinds of information based on the display signal input from the CPU 1020. The display unit 1070 may be provided with a touch panel which functions as the operating unit 1030.

Since the electronic apparatus 1000 includes the electronic component 100 capable of reducing the possibility of the mounting plate from being separated from the circuit board, for example, it is possible to improve reliability.

As the electronic apparatus 1000, various electronic apparatuses can be considered, and include, for example, a personal computer (for example, a mobile personal computer, a laptop personal computer, and a tablet personal computer), a mobile terminal, such as a smartphone or a mobile phone, a digital still camera, an inkjet ejection device (for example, an inkjet printer), a storage area network apparatus, such as a router and a switch, a local area network apparatus, an apparatus for a mobile terminal base station, a television set, a video camera, a video recorder, a car navigation system, a real time clock device, a pager, a personal digital assistance (including one having a communication function), an electronic dictionary, an electronic calculator, an electronic game machine, a gaming controller, a word processor, a workstation, a picture phone, a security television monitor, an electronic binoculars, a POS terminal, a medical instrument (for example, an electronic thermometer, a blood pressure monitor, a blood glucose monitor, an electrocardiograph, ultrasonic diagnostic equipment, and an electronic endoscope), a fish finder, a variety of measuring instruments, gauges (for example, gauges for cars, aircrafts, and boats and ships), a flight simulator, a head-mount display, a motion tracer, a motion tracker, a motion controller, and a pedestrian dead reckoning (PDR) system.

### 5. Moving Object

Next, a moving object according to this embodiment will be described referring to the drawings. FIG. 9 is a diagram (top view) showing an example of the moving object of this embodiment.

The moving object 1100 includes an electronic component according to an embodiment of the invention. Here, as shown in FIG. 9, a case where the electronic component 100 is used as an electronic component according to an embodiment of the invention will be described.

The moving object 1100 further includes controllers 1120, 1130, and 1140 which perform various kinds of control of an engine system, a brake system, a keyless entry system, and the like, a battery 1150, and a backup battery 1160. In the moving object of this embodiment, apart of the components (respective units) of FIG. 9 may be omitted, or other components may be added.

Though not shown, the electronic component 100 includes a resonator element and a heating element, and generates an oscillation signal based on the oscillation of the resonator element heated by the heating element. The oscillation signal is output from the electronic component 100 to the controllers 1120, 1130, and 1140.

The battery 1150 supplies power to the electronic component 100 and the controllers 1120, 1130, and 1140. The backup battery 1160 supplies power to the electronic component 100 and the controllers 1120, 1130, and 1140 when the output voltage of the battery 1150 falls below a threshold value.

Since the moving object 1100 includes the electronic component 100 capable of reducing the possibility of the mounting plate from being separated from the circuit board, for example, it is possible to improve reliability.

Various moving objects are considered as the moving object 1100, and for example, an automobile (including an electric automobile), an aircraft, such as a jet plane or a helicopter, a vessel, a rocket, an artificial satellite, and the like are considered.

The invention is not limited to the above-described embodiments, and various modifications may be made within the spirit and scope of the invention.

For example, in the above-described embodiments, although the mounting plate 10 is a metal plate, the mounting plate 10 is not limited to the metal plate. The mounting plate 10 may be, for example, a quartz crystal plate. For example, when the resonator element 24 is a quartz crystal resonator, a quartz crystal plate is used as the mounting plate 10, whereby it is possible to make the thermal expansion coefficients of the mounting plate 10 and the resonator element 24 the same. For this reason, it is possible to prevent deformation or separation of the mounting plate 10 and the resonator element 24 due to fluctuation in temperature between the mounting plate 10 and the resonator element 24.

For example, in the above-described embodiments, although an example where the electronic component is an oven controlled quartz crystal oscillator (OCXO) has been described, an electronic component according to an embodiment of the invention may be other kinds of devices (for example, an oscillator other than the OCXO, a sensor, or the like).

The embodiments and the modification examples described above are illustrative only, and the invention is not limited thereto. For example, the embodiments and the modification examples described above may be appropriately combined with each other.

The invention includes configurations (for example, configurations having the same function, the same way, and the same result, or configurations having the same object and the same advantages) substantially the same as the configuration described in the embodiments of the invention. Furthermore, the invention includes configurations obtained by replacing a non-essential part of the configuration described in the embodiments of the invention. Furthermore, the invention includes configurations exerting the same functional effects and configurations capable of achieving the same object as the configuration described in the embodiments of the invention. Furthermore, the invention includes configurations obtained by adding technologies known to the public to the configuration described in the embodiments of the invention.

The entire disclosure of Japanese Patent Application No. 2014-062021, filed Mar. 25, 2014 is expressly incorporated by reference herein.

What is claimed is:

1. An electronic component comprising:
a functional element;
a mounting plate which has a first surface, on which the functional element is arranged, a second surface opposite to the first surface, and an outer peripheral surface connecting the first surface and the second surface; and
a circuit board which is connected to the second surface through a connection member,
wherein the circuit board and the mounting plate are different in thermal expansion coefficient, and
the mounting plate is provided with a slit.

2. The electronic component according to claim 1,
wherein the mounting plate is a metal plate.

3. The electronic component according to claim 2,
wherein the material of the metal plate is one of copper, gold, silver, aluminum, and tungsten, or an alloy containing one of copper, gold, silver, aluminum, and tungsten as a main component.

4. The electronic component according to claim 1,
wherein the mounting plate is a quartz crystal plate.

5. The electronic component according to claim 1,
wherein two connection members are provided, and the slit is provided between the two connection members in plan view.

6. The electronic component according to claim 1,
wherein a plurality of slits are provided.

7. The electronic component according to claim 1,
wherein the mounting plate is provided with a through hole which passes through the mounting plate.

8. The electronic component according to claim 1,
wherein the functional element includes a resonator element.

9. The electronic component according to claim 8,
wherein the functional element further includes a heating element which heats the resonator element.

10. The electronic component according to claim 1, further comprising:
an electronic element,
wherein the electronic element is arranged on the circuit board, and
the mounting plate overlaps the electronic element in plan view.

11. The electronic component according to claim 10,
wherein the electronic element includes an oscillation circuit for oscillating a resonator element.

12. An electronic apparatus comprising:
the electronic component according to claim 1.

13. A moving object comprising:
the electronic component according to claim 1.
